(19) United States
(12) Patent Application Publication
(10) Pub. No.: US 2024/0284706 A1
(43) Pub. Date: Aug. 22, 2024

(54) LIGHT EMITTING ELEMENT AND MANUFACTURING METHOD OF LIGHT EMITTING ELEMENT

(71) Applicant: Samsung Display Co., LTD., Yongin-si (KR)

(72) Inventors: Bong Chun PARK, Yongin-si (KR); Kwan Jae LEE, Yongin-si (KR); Dong Eon LEE, Yongin-si (KR); So Young LEE, Yongin-si (KR); Seung A LEE, Yongin-si (KR); Jong Jin LEE, Yongin-si (KR)

(21) Appl. No.: 18/545,905

(22) Filed: Dec. 19, 2023

(30) Foreign Application Priority Data
Feb. 16, 2023 (KR) 10-2023-0021030

(51) Int. Cl. H10K 59/121; C09K 11/62; H10K 59/12; H10K 59/122; H10K 59/126; H10K 59/131; H10K 85/30

(52) U.S. Cl. CPC H10K 59/1213; C09K 11/62; H10K 59/1201; H10K 59/122; H10K 59/126; H10K 59/131; H10K 85/326

(57) ABSTRACT

A light emitting element includes: a first semiconductor layer of a first type; a first auxiliary layer on the first semiconductor layer and having a first indium composition ratio; a second auxiliary layer on the first auxiliary layer and having a second indium composition ratio; an active layer including barrier layers and well layers that are alternately arranged on the second auxiliary layer and having a third indium composition ratio; and a second semiconductor layer on the active layer and of a second type different from the first type. The second indium composition ratio is greater than the first indium composition ratio and is less than the third indium composition ratio.

### CROSS-REFERENCE TO RELATED APPLICATION

This application claims priority to and the benefit of Korean Patent Application No. 10-2023-0021030, filed in the Korean Intellectual Property Office on Feb. 16, 2023, the entire content of which is incorporated herein by reference.

### BACKGROUND

### 1. Field

Aspects of embodiments of the present disclosure relate to a light emitting element and a manufacturing method of the light emitting element.

### 2. Description of the Related Art

Recently, as interest in information display is increasing, research and development on display devices is continuously being made.

### SUMMARY

Embodiments of the present disclosure provide a light emitting element and a manufacturing method thereof that reduces or minimizes a decrease in light emitting efficiency and a change in a light emitting wavelength caused by stress and/or strain due to a difference in lattice constant between a well layer and a barrier layer in an active layer of the light emitting element.

It should be understood, however, that the aspects and features of the present disclosure are not limited to those described above, and various changes and modifications may be made without departing from the spirit and scope of the disclosure.

A light emitting element, according to an embodiment of the present disclosure, includes: a first semiconductor layer of a first type; a first auxiliary layer on the first semiconductor layer and having a first indium composition ratio; a second auxiliary layer on the first auxiliary layer and having a second indium composition ratio; an active layer including barrier layers and well layers that are alternately arranged on the second auxiliary layer and having a third indium composition ratio; and a second semiconductor layer on the active layer and of a second type different from the first type. The second indium composition ratio is greater than the first indium composition ratio and is less than the third indium composition ratio.

According to an embodiment, a thickness of the first auxiliary layer may be thicker than a thickness of the second auxiliary layer and may be thinner than the thickness of the active layer.

According to an embodiment, the first auxiliary layer may have a first gallium composition ratio, the second auxiliary layer may have a second gallium composition ratio, the active layer may have a third gallium composition ratio, and the second gallium composition ratio may be greater than the first gallium composition ratio and may be less than the third gallium composition ratio.

According to an embodiment, the active layer may include two or more pairs of the barrier layer and the well layer.

According to an embodiment, each of the first auxiliary layer and the second auxiliary layer may include one or more pairs of a first thin film layer and a second thin film layers, and a thickness of the well layer of the active layer may be thicker than a thickness of the first thin film layer of the first auxiliary layer and the second auxiliary layer.

According to one embodiment, the first thin film layer may include GaN, and the second thin film layer may include InGaN.

According to an embodiment, a thickness of the barrier layer may be thicker than a thickness of the first thin film layer of the second auxiliary layer and may be thinner than the thickness of the first thin film layer of the first auxiliary layer.

According to an embodiment, the first thin film layer of the second auxiliary layer adjacent to the active layer may directly contact the barrier layer of the active layer.

According to an embodiment, a number of the barrier layer and the well layer of the active layer may be greater than a number of the first thin film layer and the second thin film layer of the first auxiliary layer.

According to an embodiment, the thickness of the second thin film layer of the second auxiliary layer may be equal to or thicker than the thickness of the second thin film layer of the first auxiliary layer.

According to an embodiment, the thickness of the first thin film layer of the first auxiliary layer may be thicker than the thickness of the first thin film layer of the second auxiliary layer.

According to an embodiment, a number of the first thin film layer and the second thin film layer of the second auxiliary layer may be greater than a number of the first thin film layer and the second thin film layer of the first auxiliary layer.

According to an embodiment, the first auxiliary layer may include five pairs of the first thin film layer and the second thin film layer, the second auxiliary layer may include eight pairs of the first thin film layer and the second thin film layer, and the active layer may include eight pairs of the well layer and the barrier layer.

According to an embodiment, the first indium composition ratio may be 4% or less, the second indium composition ratio may be between 4% and 13%, and the third indium composition ratio may be between 15% and 17%.

According to an embodiment, the first semiconductor layer may be a semiconductor layer doped with an n-type dopant, and the second semiconductor layer may be a semiconductor layer doped with a p-type dopant.

A manufacturing method of a light emitting element, according to an embodiment of the present disclosure, includes sequentially forming a first semiconductor layer, a first auxiliary layer, a second auxiliary layer, an active layer, and a second semiconductor layer in a first direction on a stacked substrate; and etching the first semiconductor layer, the first auxiliary layer, the second auxiliary layer, the active layer, and the second semiconductor layer in a thickness direction of the stacked substrate to form a light emitting element. The forming of the first auxiliary layer on the first semiconductor layer includes alternately disposing one more pairs of a first thin film layer having a first indium composition ratio and a second thin film layer having a first gallium composition ratio, the forming of the second auxiliary layer on the first auxiliary layer includes alternately disposing one more pairs of a third thin film layer having a second indium composition ratio and a fourth thin film layer having a second gallium composition ratio, the forming of the active layer on the second auxiliary layer includes alternately disposing two or more pairs of well layers having a third indium composition ratio and barrier layers having a third gallium composition ratio, and the second indium composition ratio has a value between the first indium composition ratio and the third indium composition ratio.

According to an embodiment, the second gallium composition ratio may have a valve between the first gallium composition ratio and the third gallium composition ratio.

According to an embodiment, a thickness of the second auxiliary layer in the first direction may be thicker than a thickness of the first auxiliary layer and may be thinner than a thickness of the active layer.

According to an embodiment, a thickness of the first thin film layer of the first auxiliary layer may be thicker than a thickness of the third thin film layer of the second auxiliary layer.

A display device, according to an embodiment of the present disclosure, includes: a substrate; a light emitting element on the substrate and having a first end and a second end facing the first end; a first pixel electrode electrically connected to the second end of the light emitting element; and a second pixel electrode electrically connected to the first end of the light emitting element. The light emitting element includes a second semiconductor layer, an active layer, a second auxiliary layer, and a first semiconductor layer sequentially arranged in a first direction, and the second indium composition ratio of the second auxiliary layer is greater than the first indium composition ratio of the first auxiliary layer and is less than the third indium composition ratio of the active layer.

A light emitting element and a manufacturing method thereof, according to embodiments of the present disclosure, can minimize or improve a decrease in a quantum efficiency and a wavelength change by disposing an auxiliary layer having an indium composition ratio between the indium composition ratio of the active layer and the indium composition ratio of a superlattice layer between the active layer and the superlattice layer of the light emitting element. In addition, the light emitting element and the manufacturing method thereof, according to embodiments of the present disclosure, can block defective elements from flowing into the active layer through a stress control layer, thereby improving reliability.

It should be understood, however, that the aspects and features of the present disclosure are not limited to those described above, and various changes and modifications may be made without departing from the spirit and scope of the present disclosure.

### BRIEF DESCRIPTION OF THE DRAWINGS

FIG. 1 is a perspective view of a light emitting element according to an embodiment of the present disclosure.

FIG. 2 is a cross-sectional view of the light emitting element shown in FIG. 1.

FIG. 3 is a cross-sectional view of a stacked structure of the light emitting element shown in FIG. 1.

FIG. 4 is a cross-sectional view of a stacked structure of a light emitting element according to a comparative example.

FIG. 5 is a cross-sectional view of a stacked structure of the light emitting element shown in FIG. 3.

FIG. 6 is a graph showing composition ratios of the first and second auxiliary layers and the active layer shown in FIG. 5.

FIG. 7 is a graph showing luminance change rate according to embodiments of the present disclosure and a comparative example.

FIG. 8 is a schematic plan view of a display device according to an embodiment of the present disclosure.

FIG. 9 is a circuit diagram of a sub-pixel included in the display device shown in FIG. 8.

FIG. 10 is a schematic plan view of a sub-pixel included in the display device shown in FIG. 8.

FIG. 11 is a schematic cross-sectional view taken along the line I-I′ of FIG. 10.

FIGS. 12 to 15 are schematic plan views of steps of a manufacturing method of a light emitting element according to an embodiment of the present disclosure.

### DETAILED DESCRIPTION

Hereinafter, embodiments of the present disclosure will be described, in detail, with reference to the accompanying drawings.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

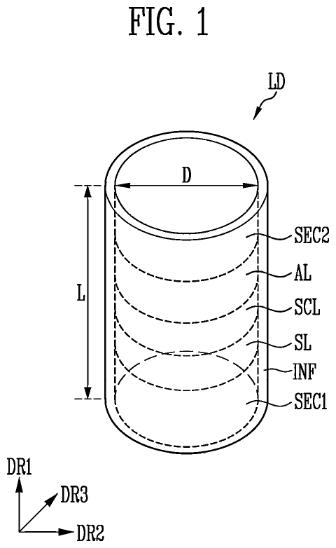

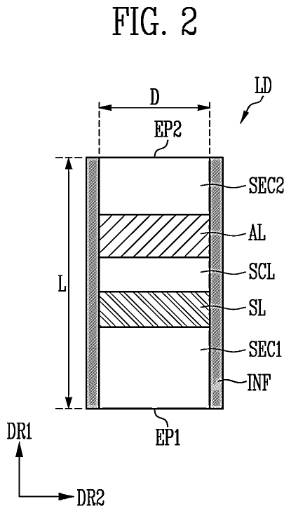

FIG. 1 is a perspective view of a light emitting element according to an embodiment of the present disclosure, and FIG. 2 is a cross-sectional view of the light emitting element shown in FIG. 1.

Referring to FIGS. 1 and 2, the light emitting element LD includes a first semiconductor layer SEC1, a second semiconductor layer SEC2, a first auxiliary layer SL, a second auxiliary layer SCL, and an active layer AL interposed between the first and second semiconductor layers SEC1 and SEC2. In an embodiment, the light emitting element LD may be implemented as a light emitting stack (e.g., in a stacked pattern or arrangement) in which the first semiconductor layer SEC1, the first auxiliary layer SL, the second auxiliary layer SCL, the active layer AL, and the second semiconductor SEC2 are sequentially stacked in a first direction DR1.

The light emitting element LD may be provided in (e.g., may be formed in and/or the elements thereof may be stacked in) a direction extending in one direction (e.g., an extension direction). When the extension direction of the light emitting element LD is referred to as a length direction, the light emitting element LD may have a first end EP1 and a second end EP2 in the length direction. The first semiconductor layer SEC1 may be disposed at the first end EP1 of the light emitting element LD, and the second semiconductor layer SEC2 may be disposed at the second end EP2 of the light emitting element LD.

The light emitting element LD have (e.g., may be formed in) various shapes. For example, the light emitting element LD may have a rod-like shape, a bar-like shape, or a column shape that is longest (e.g., has an aspect ratio greater than 1) in the length direction L (e.g., in the first direction DR1). In other embodiments, the light emitting element LD may have a rod-like shape, bar-like shape, or a column shape that is shortest (e.g., has an aspect ratio less than 1) in the length direction L (e.g., in the first direction DR1). In other embodiments, the light emitting element LD may have a rod-like shape, a bar-like shape, or a column shape with an aspect ratio of one.

For example, the light emitting element LD may include (or may be) a light emitting diode (LED) manufactured to be extremely small to have a diameter (D) and/or a length (L) of a nano scale (or nanometer) to micro scale (or micrometer).

When the light emitting element LD is longest in the first direction DR1 (e.g., has an aspect ratio greater than 1), the diameter D of the light emitting element LD may be in a range of about 0.5 μm to about 6 μm, and the length (L) thereof may be in a range of about 1 μm to about 10 μm. However, the diameter (D) and length (L) of the light emitting element LD are not limited thereto, and the size of the light emitting element LD may be changed to meet application requirements or design conditions of a lighting device or a self-luminous display device to which the light emitting element LD is applied.

The first semiconductor layer SEC1 may include, for example, at least one n-type semiconductor layer. The first semiconductor layer SEC1 may have an upper surface contacting the first auxiliary layer SL and a lower surface exposed to the outside in the length direction of the light emitting element LD. The lower surface of the first semiconductor layer SEC1 may be (or may form) the first end EP1 of the light emitting element LD.

The first auxiliary layer SL may be disposed between the first semiconductor layer SEC1 and the second auxiliary layer SCL. One surface of the first auxiliary layer SL may contact the first semiconductor layer SEC1, and the other (e.g., the opposite) surface of the first auxiliary layer SL may contact the second auxiliary layer SCL. The first auxiliary layer SL may be a strain relieving layer that acts as a buffer to reduce a difference in lattice constant between the first semiconductor layer SEC1 and the active layer AL. The first auxiliary layer SL may be disposed adjacent to the first semiconductor layer SEC1 and may reduce or prevent the generation of defects in the first semiconductor layer SEC1.

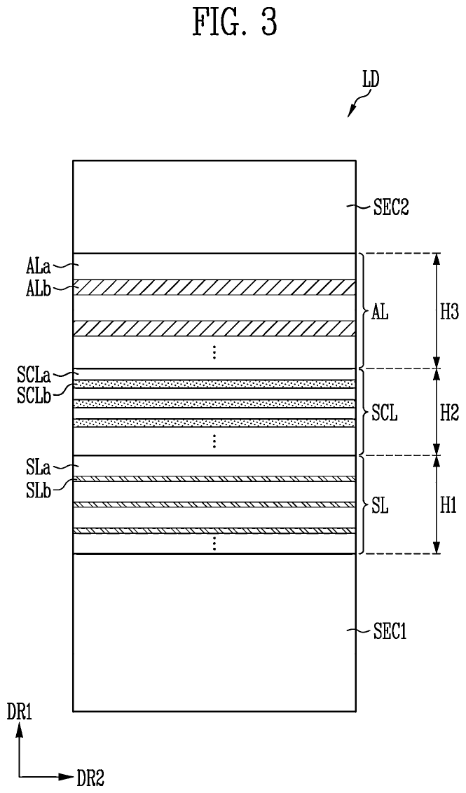

The first auxiliary layer SL may have a stacked structure in which a plurality of thin film layers (see, e.g., first and second thin film layers SLa and SLb shown in FIG. 3) are alternately disposed. The first auxiliary layer SL may be a strained layer superlattice (SLS). The first auxiliary layer SL may include indium gallium nitride (InGaN) and gallium nitride (GaN).

The second auxiliary layer SCL may be disposed between the first auxiliary layer SL and the active layer AL. One surface of the second auxiliary layer SCL may contact the first auxiliary layer SL, and the other (e.g., the opposite) surface of the second auxiliary layer SCL may contact the active layer AL. The second auxiliary layer SCL may be an auxiliary layer for minimizing or improving a quantum-confined stark effect (QCSE) generated due to a lattice mismatch with the active layer AL. The second auxiliary layer SCL may have a stacked structure in which a plurality of thin film layers (see, e.g., third and fourth thin film layers SCLa and SCLb shown in FIG. 3) are alternately disposed. In one embodiment, the second auxiliary layer SCL may include indium gallium nitride (InGaN) and gallium nitride (GaN).

In one embodiment, an indium composition ratio of the second auxiliary layer SCL may be different from an indium composition ratio of the first auxiliary layer SL. For example, the indium composition ratio of the second auxiliary layer SCL may be higher (or greater) than that of the first auxiliary layer SL.

In one embodiment, the first auxiliary layer SL may have a thicker thickness than (e.g., may be thicker than) the second auxiliary layer SCL in the length direction of the light emitting element LD.

The active layer AL may be disposed on the second auxiliary layer SCL and may have a single quantum well (SQW) structure or a multi-quantum well (MQW) structure. In one embodiment, when the active layer AL has a multi quantum well structure, a barrier layer and a well layer may form a pair (or unit) and may be periodically and repeatedly stacked. In another embodiment, the active layer AL may include a strain reinforcing layer between the barrier layer and the well layer. The strain reinforcing layer may have a smaller lattice constant than the barrier layer to further intensify a strain (e.g., a compressive strain) applied to the well layer. However, a structure of the active layer AL is not limited to the above-described embodiment.

The active layer AL may emit light having a wavelength in a range of about 400 nm to about 900 nm and may have a double heterostructure (also called a double heterojunction). The active layer AL may have a lower surface contacting the second auxiliary layer SCL and an upper surface contacting the second semiconductor layer SEC2.

A color (e.g., an emission color) of the light emitting element LD may be determined according to a wavelength of light emitted from the active layer AL. The color of the light emitting element LD may determine a color of a corresponding pixel. For example, the light emitting element LD may emit red light, green light, or blue light.

When an electric field have a reference (or predetermined) voltage or more is applied to opposite ends of the light emitting element LD, the light emitting element LD emits light by forming electron-hole pairs in the active layer AL. By controlling the light emission of the light emitting element LD by using this principle, the light emitting element LD may be used as a light source (e.g., as a light emitting source) in various light emitting devices, including pixels of a display device.

The second semiconductor layer SEC2 may be disposed on the upper surface of the active layer AL and may include a semiconductor layer of a different type from that of the first semiconductor layer SEC1. For example, the second semiconductor layer SEC2 may include at least one p-type semiconductor layer. The second semiconductor layer SEC2 may have a lower surface contacting the second surface of the active layer AL and an upper surface exposed to the outside in the length direction of the light emitting element LD. The upper surface of the second semiconductor layer SEC2 may be (or may form) the second end EP2 of the light emitting element LD.

The first semiconductor layer SEC1 and the second semiconductor layer SEC2 may have different thicknesses in the length direction of the light emitting element LD. For example, the first semiconductor layer SEC1 may have a thicker thickness than the second semiconductor layer SEC2 in the length direction of the light emitting element LD. Accordingly, the active layer AL of the light emitting element LD may be disposed closer to the upper surface of the second semiconductor layer SEC2 (e.g., closer to the second end EP2) than to the lower surface of the first semiconductor layer SEC1 (e.g., than to the first end EP1).

In addition to the above-described first semiconductor layer SEC1, active layer AL, and second semiconductor layer SEC2, the light emitting element LD may further include a contact electrode disposed on the second semiconductor layer SEC2. Also, according to another embodiment, another contact electrode disposed on one end of the first semiconductor layer SEC1 may be further included.

Each of the first and second contact electrodes may be an ohmic contact electrode but are not limited thereto. According to various embodiments, the first and second contact electrodes may be Schottky contact electrodes. The first and second contact electrodes may include a conductive material.

The light emitting element LD may further include an insulating film INF (or an insulating coating). However, according to embodiments, the insulating film INF may be omitted or may be provided to cover only a portion of the first semiconductor layer SEC1, the active layer AL, and the second semiconductor layer SEC2.

The insulating film INF may prevent an electrical short circuit that can occur if the active layer AL contacts a conductive material other than the first and second semiconductor layers SEC1 and SEC2. In addition, the insulating film INF may reduce or minimize surface defects of the light emitting element LD to improve a lifespan and a light emitting efficiency of the light emitting element LD. As long as the active layer AL is prevented from short circuiting with an external conductive material, the presence or absence of the insulating film INF is not limited.

The insulating film INF may surround at least a portion of an outer circumferential surface of a light emitting stack including the first semiconductor layer SEC1, the first auxiliary layer SL, the second auxiliary layer SCL, the active layer AL, and the second semiconductor layer SEC2.

In the above-described embodiment, the insulating film INF has been described as entirely surrounding outer circumferential surfaces of the first semiconductor layer SEC1, the active layer AL, and the second semiconductor layer SEC2, but it is not limited thereto.

The insulating film INF may include a transparent insulating material. For example, the insulating film INF may include one or more insulating materials selected from a group consisting of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanium strontium oxide (SrTiOₓ), cobalt oxide (CoₓO_{y}), magnesium oxide (MgO), zinc oxide (ZnOₓ), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InₓO_{y}:H, niobium oxide (NbₓO_{y}), magnesium fluoride (MgFₓ), aluminum fluoride (AlFₓ), alucone polymer film (e.g., aluminum alkoxide metalcone film), titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), vanadium nitride (VN), etc. but is not limited thereto and various materials having insulating properties may be used as a material of the insulating film INF.

The insulating film INF may be provided as a single layer or as multiple layers, such as a double layer.

The light emitting element LD described above may be used as a light emitting source (or light source) of various display devices. The light emitting element LD may be manufactured through a surface treatment process. For example, when a plurality of light emitting elements LD is mixed with a fluid solution (e.g., a solvent) and supplied to (e.g., deposited or printed in) each pixel area (e.g., an emission area of each pixel or an emission area of each sub-pixel), each light emitting element LD may be surface-treated so that the light emitting elements LD may be uniformly sprayed without non-uniform agglomeration in the solution.

A light emitting unit (or a light emitting device) including the above-described light emitting elements LD may be used in various types of electronic devices that require a light source, including a display device. For example, when a plurality of light emitting elements LD are disposed in a pixel area of each pixel of a display panel, the light emitting elements LD may be used as a light source of each pixel. However, a field of application of the light emitting element LD is not limited to the embodiment described above. For example, the light emitting element LD may be used in other types of electronic devices that require a light source, such as a lighting device.

Further, the light emitting element LD applied to the display device as described above is not limiting. For example, the light emitting element LD may be a micro light emitting diode of a flip chip type or an organic light emitting element including an organic light emitting layer.

FIG. 3 is a cross-sectional view of a stacked structure of the light emitting element shown in FIG. 1.

Referring to FIG. 3, each of the first and second auxiliary layers SL and SCL and the active layer AL may have a multi-thin film stack structure including a plurality of thin film layers.

The first auxiliary layer SL, the second auxiliary layer SCL, and the active layer AL may be sequentially disposed (or stacked) in the first direction DR1.

The first auxiliary layer SL may include a first thin film layer SLa and a second thin film layer SLb. The first auxiliary layer SL may be a strained layer superlattice (SLS) in which the first thin film layer SLa and the second thin film layer SLb are alternately disposed.

The first auxiliary layer SL may have a multilayer structure in which a plurality of first thin film layers SLa and a plurality of second thin film layers SLb are alternately and sequentially stacked. The first thin film layer SLa and the second thin film layer SLb may form a unit (or a pair), and a plurality of units may be stacked on the first semiconductor layer SEC1. In one embodiment, the first auxiliary layer SL may include at least one pair of the first thin film layer SLa and the second thin film layer SLb. However, it is not limited thereto, and the first auxiliary layer SL may include one to five pairs of first and second thin film layers SLa and SLb.

The first thin film layer SLa may include GaN, and the second thin film layer SLb may include InGaN, but the layers are not limited thereto. In one embodiment, the indium composition ratio of the second thin film layer SLb may be higher than the indium composition ratio of the first thin film layer SLa. In one embodiment, when the first thin film layer SLa includes only GaN material, the indium composition ratio of the first auxiliary layer SL may be the same as the indium composition ratio of the second thin film layer SLb.

In one embodiment, the first and second thin film layers SLa and SLb may be doped with a relatively small amount of first conductive type dopant (e.g., Si). The first conductive type dopant may include an n-type conductive type dopant. A concentration of the first conductive type dopants provided to the first auxiliary layer SL may be lower than a concentration of dopants provided to the first semiconductor layer SEC1.

The plurality of first thin film layers SLa may have the same thickness in the first direction DR1 but are not limited thereto. In a manufacturing process for the plurality of first thin film layers SLa, the thicknesses of the plurality of first thin film layers SLa may be different from each other according to a process condition for each of the plurality of first thin film layers SLa.

The thickness of the first thin film layer SLa may be thicker than that of the second thin film layer SLb. For example, the thickness of the first thin film layer SLa may be about 10 nm, and the thickness of the second thin film layer SLb may be about 1 nm. Thus, the thickness of the pair of first thin film layer SLa and second thin film layer SLb may be about 11 nm in one embodiment.

The first auxiliary layer SL may have a first thickness H1. The first thickness H1 may be a sum of the thicknesses of the plurality of first thin film layers SLa and the plurality of second thin film layers SLb in the first direction DR1. Accordingly, the first thickness H1 of the first auxiliary layer SL may vary according to the number of the first and second thin film layers SLa and SLb. For example, when the first auxiliary layer SL includes five pairs of first and second thin film layers SLa and SLb, the first thickness H1 may be about 55 nm.

In one embodiment, the first thickness H1 may be thicker than a second thickness H2 of the second auxiliary layer SCL but thinner than a third thickness H3 of the active layer AL.

The second auxiliary layer SCL may include a third thin film layer SCLa (or a first thin film layer of the second auxiliary layer SCL) and a fourth thin film layer SCLb (or a second thin film layer of the second auxiliary layer SCL).

The second auxiliary layer SCL may have a multilayer structure in which a plurality of third thin film layers SCLa and a plurality of fourth thin film layers SCLb are alternately and sequentially stacked. The third thin film layer SCLa and the fourth thin film layer SCLb may form a unit (or a pair), and a plurality of units may be stacked on the first auxiliary layer SL. In one embodiment, the second auxiliary layer SCL may include at least one pair of the third thin film layer SCLa and the fourth thin film layer SCLb. However, it is not limited thereto, and the second auxiliary layer SCL may include five to nine pairs of third and fourth thin film layers SCLa and SCLb.

The third thin film layer SCLa may include GaN, and the fourth thin film layer SCLb may include InGaN, but are not limited thereto. In one embodiment, the indium composition ratio of the fourth thin film layer SCLb may be higher than the indium composition ratio of the third thin film layer SCLa. In one embodiment, when the third thin film layer SCLa includes only GaN material, the indium composition ratio of the second auxiliary layer SCL may be the same as the indium composition ratio of the fourth thin film layer SCLb.

The plurality of third thin film layers SCLa may have the same thickness in the first direction DR1 but are not limited thereto. In a manufacturing process for the plurality of third thin film layers SCLa, the thicknesses of the plurality of third thin film layers SCLa may be different from each other according to process conditions for the plurality of third thin film layers SCLa.

The thickness of the third thin film layer SCLa may be thicker than that of the fourth thin film layer SCLb. For example, the thickness of the third thin film layer SCLa may be about 4 nm, and the thickness of the fourth thin film layer SCLb may be about 1 to 2 nm. Thus, the thickness of the pair of third and fourth thin film layers SCLa and SCLb may be about 5 to 6 nm in one embodiment.

The second auxiliary layer SCL may have a second thickness H2. The second thickness H2 may be a sum of the thickness of the plurality of third thin film layers SCLa in the first direction DR1 and the thickness of the plurality of fourth thin film layers SCLb in the first direction DR1. Accordingly, the second thickness H2 of the second auxiliary layer SCL may vary according to the number of the third and fourth thin film layers SCLa and SCLb included in the second auxiliary layer SCL. For example, when the second auxiliary layer SCL includes eight pairs of third and fourth thin film layers SCLa and SCLb, the second thickness H2 may be in a range of about 40 nm to about 48 nm.

In one embodiment, the second thickness H2 may be thinner than each of the first thickness H1 and the third thickness H3.

In one embodiment, the first thin film layer SLa of the first auxiliary layer SL may have the same composition as the third thin film layer SCLa of the second auxiliary layer SCL but is not limited thereto. In one embodiment, the first thin film layer SLa and the third thin film layer SCLa may have the same composition but different composition ratios. For example, the gallium composition ratio (hereinafter referred to as second gallium composition ratio) of the third thin film layer SCLa may be higher than the gallium composition ratio (hereinafter referred to as first gallium composition ratio) of the first thin film layer SLa.

In one embodiment, the thickness of the first thin film layer SLa in the first direction DR1 may be thicker than the thickness of the third thin film layer SCLa in the first direction DR1.

In one embodiment, the second thin film layer SLb of the first auxiliary layer SL may have the same composition as the fourth thin film layer SLCb of the second auxiliary layer SCL but is not limited thereto. In one embodiment, the second thin film layer SLb and the fourth thin film layer SCLb may have the same composition but different composition ratios. For example, the indium composition ratio of the fourth thin film layer SCLb may be higher than the indium composition ratio of the second thin film layer SLb.

In one embodiment, the thickness of the fourth thin film layer SCLb in the first direction DR1 may be same as or thicker than the thickness of the second thin film layer SLb in the first direction DR1.

The active layer AL may include a barrier layer ALa and a well layer ALb. The active layer AL may have a multi quantum well structure, and the active layer AL may have a multi quantum well structure in which a plurality of barrier layers ALa and a plurality of well layers ALb are alternately and sequentially stacked. The barrier layer ALa and the well layer ALb may form a unit (or a pair), and a plurality of units may be stacked on the second auxiliary layer SCL. In one embodiment, the active layer AL may include at least two pairs of barrier layers ALa and well layers ALb. However, it is not limited thereto, and the active layer AL may have a well structure of five to nine pairs.

In one embodiment, the barrier layer ALa adjacent to the second auxiliary layer SCL may be directly disposed on the first thin film layer SCLa adjacent to the active layer AL.

The barrier layer ALa and the well layer ALb may have different compositions. For example, the well layer ALb may include at least one of GaInP, AlGaInP, InGaN, and InGaAsP. The barrier layer ALa may include at least one of GaN, AlGaP, and AlGaAs. For example, the well layer ALb may have an indium composition ratio higher than that of the barrier layer ALa. In one embodiment, the plurality of barrier layers ALa may have the same composition. The plurality of well layers ALb may have the same composition.

The active layer AL may have a multi quantum well structure, and the plurality of barrier layers ALa included in the active layer AL may have the same thickness (or substantially the same thickness) in the first direction DR1 but is not limited thereto. In a manufacturing process for the plurality of barrier layers ALa, the thicknesses of the plurality of barrier layers ALa may be different from each other according to a process condition for each of the plurality of barrier layers ALa.

The thickness of the barrier layer ALa in the first direction DR1 may be thicker than the thickness of the well layer ALb. For example, the barrier layer ALa may have a thickness of about 6 nm and the well layer ALb may have a thickness of about 3 nm. Thus, the pair of barrier layer ALa and well layer ALb may have a thickness of about 9 nm in one embodiment.

The barrier layer ALa may have the same composition as the first thin film layer SLa and the third thin film layer SCLa but is not limited thereto. For example, the barrier layer ALa may have a composition and composition ratio different from those of the first thin film layer SLa and the third thin film layer SCLa.

The well layer ALb may have the same composition as the second thin film layer SLb and the fourth thin film layer SCLb but is not limited thereto. For example, the well layer ALb may have a composition and composition ratio different from those of the second thin film layer SLb and the fourth thin film layer SCLb.

In one embodiment, the gallium composition ratio of the barrier layer ALa (hereinafter referred to as a third gallium composition ratio) may be higher than the gallium composition ratio of each of the first thin film layer SLa and the third thin film layer SCLa. The indium composition ratio of the well layer ALb may be higher than that of each of the second thin film layer SLb and the fourth thin film layer SCLb.

The active layer AL may have a third thickness H3. The third thickness H3 may be a sum of the thicknesses of the plurality of barrier layers ALa and the plurality of well layers ALb in the first direction DR1. Accordingly, the third thickness H3 of the active layer AL may vary according to the number of barrier layers ALa and well layers ALb. For example, when the active layer AL includes eight pairs of barrier layers ALa and well layers ALb, the third thickness H3 may be about 72 nm.

When the composition of the plurality of barrier layers ALa is the same, the composition ratios of the plurality of barrier layers ALa may be different from each other but are not limited thereto and may be the same. When the composition of the plurality of well layers ALb is the same, the composition ratios of the plurality of well layers ALb may be different from each other but are not limited thereto and may be the same.

In one embodiment, the barrier layer ALa may have the same composition as the first thin film layer SLa and the third thin film layer SCLa. For example, the first thin film layer SLa, the third thin film layer SCLa, and the barrier layer ALa may include GaN but are not limited thereto. In one embodiment, the thickness of the barrier layer ALa may be thinner than the first thin film layer SLa and thicker than the third thin film layer SCLa.

In one embodiment, the well layer ALb may have the same composition as the second thin film layer SLb and the fourth thin film layer SCLb. For example, the second thin film layer SLb, the fourth thin film layer SCLb, and the well layer ALb may include InGaN but are not limited thereto. In one embodiment, the thickness of the well layer ALb may be thicker than that of the second thin film layer SLb and the fourth thin film layer SCLb.

Electrons injected from the first semiconductor layer SEC1 and holes injected from the second semiconductor layer SEC2 may be recombined in the well layer(s) ALb, and accordingly, light corresponding to a band gap energy of the well layer(s) ALb may be emitted.

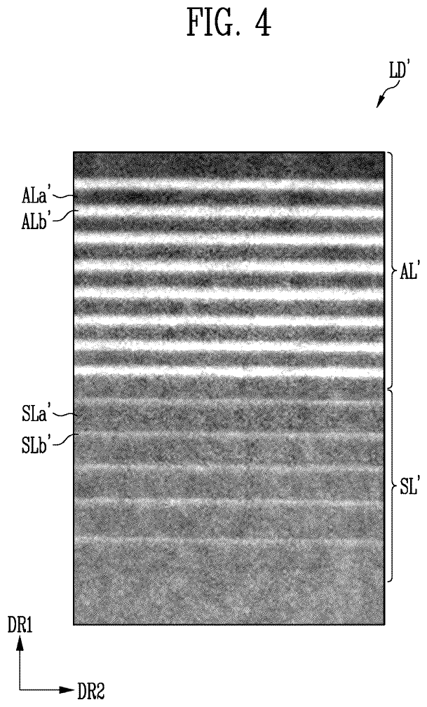

FIG. 4 is a cross-sectional view of a stacked structure of a light emitting element according to a comparative example.

Referring to FIG. 4, a light emitting element LD′ may include a first auxiliary layer SL′ and an active layer AL′ sequentially stacked in the first direction DR1. The active layer AL′ may be directly disposed on the first auxiliary layer SL′. A first thin film layer SLa′ of the first auxiliary layer SL′ may include GaN, and a second thin film layer SLb′ thereof may include InGaN.

When the barrier layer ALa′ includes GaN and the well layer ALb′ includes InGaN, and the barrier layer ALa′ and the well layer ALb′ are alternately and sequentially disposed on the first auxiliary layer SL′, stress and strain may act relatively strongly due to a difference of a lattice constant between the barrier layer ALa′ and the well layer ALb′ or a high indium (In) content of the well layer ALb′. This will cause a quantum confined stark effect (QCSE) to appear, resulting in a decrease in a light emitting efficiency (e.g., an external quantum efficiency (EQE)) and a change in a wavelength of emitted light (e.g., a color shift).

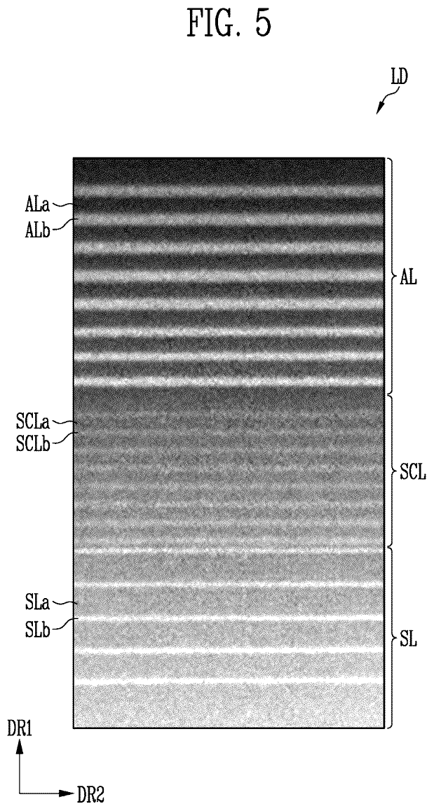

FIG. 5 is a cross-sectional view of a stacked structure of the light emitting element shown in FIG. 3.

Referring to FIG. 5, the second auxiliary layer SCL may be disposed between the active layer AL and the first auxiliary layer SL of the light emitting element LD compared to the comparative example shown in FIG. 4.

In one embodiment, the indium composition ratio of the second auxiliary layer SCL may be greater than the indium composition ratio of the first auxiliary layer SL and may be less than the indium composition ratio of the active layer AL. In one embodiment, the indium composition ratio of the first auxiliary layer SL may be about 4%, the indium composition ratio of the second auxiliary layer SCL may be about 4% to about 13%, and the indium composition ratio of the active layer AL may be about 15% to about 17%.

In the light emitting element LD according to embodiments of the present disclosure, because the second auxiliary layer SCL is disposed between the active layer AL and the first auxiliary layer SL, even if the indium composition ratio of the active layer AL increases, stress and/or strain generated from the active layer AL may be minimized or improved, thereby preventing a change in a wavelength and increasing a light emitting efficiency.

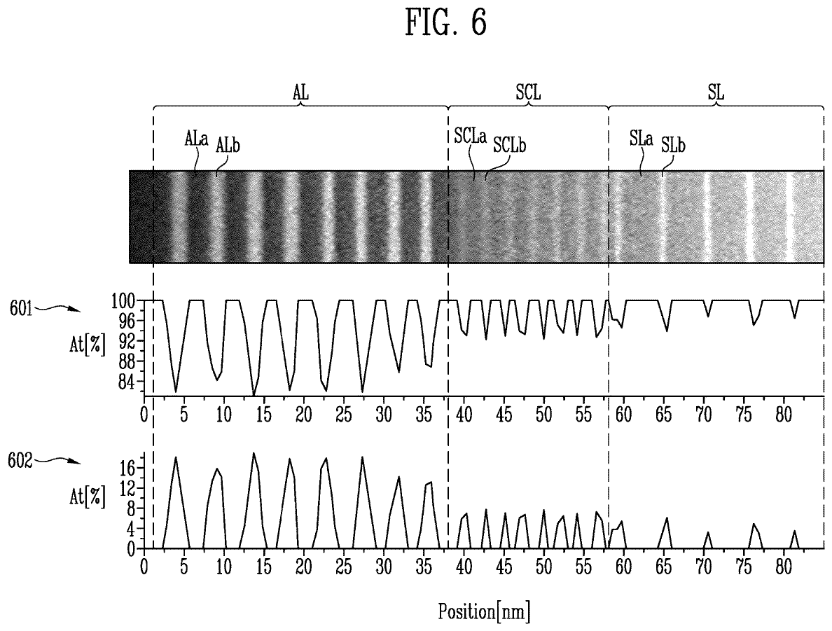

FIG. 6 is a graph showing composition ratios of the first and second auxiliary layers and the active layer shown in FIG. 5.

Referring to FIG. 6, a graph 601 shows the gallium composition ratio of each of the barrier layer ALa of the active layer AL, the first thin film layer SLa of the first auxiliary layer SL, and the third thin film layer SCLa of the second auxiliary layer SCL, and a graph 602 shows the indium composition of each of the well layer ALb of the active layer AL, the second thin film layer SLb of the first auxiliary layer SL, and the fourth thin film layer SCLb of the second auxiliary layer SCL.

Referring to the graph 601, the gallium composition ratio of the barrier layer ALa may be higher than that of the first thin film layer SLa and the third thin film layer SCLa. In one embodiment, the gallium composition ratio of the third thin film layer SCLa may be higher than that of the first thin film layer SLa and lower than that of the barrier layer ALa.

Referring to the graph 602, the indium composition ratio of the well layer ALb may be higher than that of the second thin film layer SLb and the fourth thin film layer SCLb. In one embodiment, the indium composition ratio of the fourth thin film layer SCLb may be higher than the indium composition ratio of the second thin film layer SLb and lower than the indium composition ratio of the well layer ALb.

The light emitting element LD, according to an embodiment of the present disclosure, can relieve the stress and/or strain generated in the active layer AL due to the second auxiliary layer SCL having an indium composition ratio between the indium composition ratio of the first auxiliary layer SL and the indium composition ratio of the active layer AL.

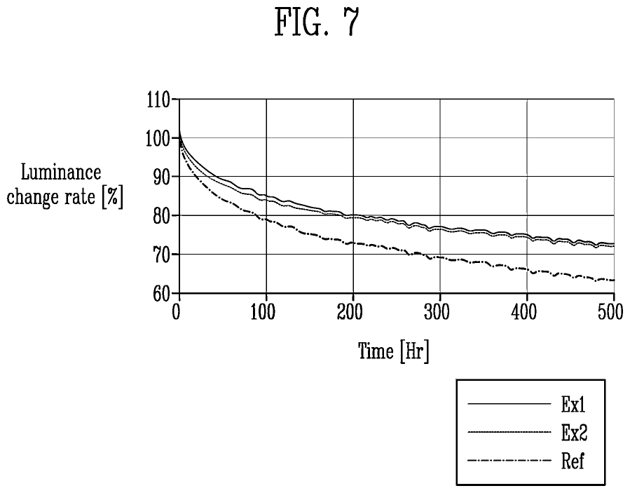

FIG. 7 is a graph showing luminance change rates according to embodiments of the present disclosure and a comparative example.

Referring to FIG. 7, the comparative example Ref shows a luminance change rate of the light emitting element LD′ shown in FIG. 4 when the thickness of the second thin film layer SLb′ is about 1 nm. The first embodiment Ex1 shows the luminance change rate of the light emitting element LD shown in FIG. 3 when the thickness of the second thin film layer SLb of the first auxiliary layer SL is about 1 nm and the thickness of the fourth thin film layer SCLb of the second auxiliary layer SCL is about 1 nm. The second embodiment Ex2 shows the luminance change rate of the light emitting element LD shown in FIG. 3 when the thickness of the second thin film layer SLb of the light emitting element LD is about 1 nm, and the thickness of the fourth thin film layer SCLb of the second auxiliary layer SCL is about 2 nm.

The luminance change rate of the first and second embodiments Ex1 and Ex2 may be less than that of the comparative example Ref. That is, the light emitting element LD, according to embodiments of the present disclosure, includes the second auxiliary layer SCL disposed between the first auxiliary layer SL and the active layer AL to relieve the strain caused by the difference in lattice constant, thereby minimizing (or improving) the luminance change rate to secure reliability.

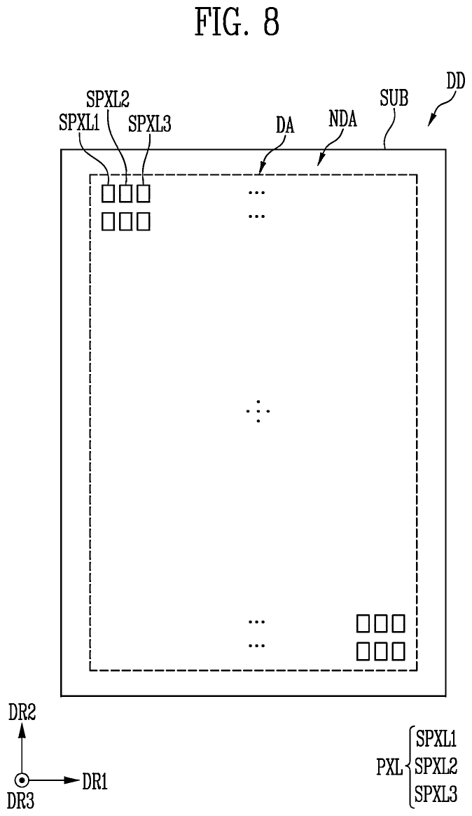

FIG. 8 is a schematic plan view of a display device according to an embodiment of the present disclosure.

In FIG. 8, a structure of a display device DD is schematically illustrated focusing on a display area DA. However, at least one driving circuit unit (e.g., at least one of a scan driver and a data driver), lines, and/or pads may be further disposed on the display device DD according to various embodiments.

The present disclosure may be applied to the display device DD when the display device DD is an electronic device having a display surface formed on at least one surface thereof, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical equipment, a camera, a wearable, and the like.

Referring to FIG. 8, the display device DD may include a substrate SUB (e.g., a base layer) and a pixel PXL provided on the substrate SUB.

The display device DD may have various shapes. For example, the display device DD may be provided in a rectangular plate shape but is not limited thereto. For example, the display device DD may have a circular or oval shape. Also, the display device DD may have angled corners and/or curved corners. For convenience, in FIG. 8, the display device DD is illustrated as having a rectangular plate shape. In addition, in FIG. 8, an extending direction (e.g., a horizontal direction) of a short side of the display device DD is indicated as the first direction DR1, and an extending direction (e.g., a vertical direction) of a long side thereof is indicated as the second direction DR2.

The substrate SUB may constitute a base member of the display device DD and may be a rigid or flexible substrate or film. For example, the substrate SUB may be a rigid substrate made of glass or tempered glass, a flexible substrate (or a thin film) made of plastic or metal, or one or more insulating layers. The material and/or physical properties of the substrate SUB are not particularly limited.

The substrate SUB (and the display device DD) may have a display area DA for displaying an image and a non-display area NDA excluding the display area DA. The display area DA may constitute a screen at where an image is displayed, and the non-display area NDA may be disposed on at least one side of the display area DA, for example, the non-display area NDA may surround (e.g., may extend around a periphery of) the display area DA but is not limited thereto.

The pixel PXL may be disposed in the display area DA on the substrate SUB. The non-display area NDA may be disposed around the display area DA. Various lines, pads, and/or embedded circuits connected to the pixels PXL of the display area DA may be disposed in the non-display area NDA.

In describing embodiments of the present disclosure, the term “connection (or access)” may mean a physical and/or electrical connection (or access) collectively and may refer to a direct or indirect connection (or access) and an integral or non-integral connection (or access) collectively.

The pixel PXL may include sub-pixels SPXL1 to SPXL3. For example, the pixel PXL may include a first sub-pixel SPXL1, a second sub-pixel SPXL2, and a third sub-pixel SPXL3.

Each of the sub-pixels SPXL1 to SPXL3 may emit light of a color (e.g., a predetermined color). According to embodiments, the sub-pixels SPXL1 to SPXL3 may emit light of different colors. For example, the first sub-pixel SPXL1 may emit light of a first color, the second sub-pixel SPXL2 may emit light of a second color, and the third sub-pixel SPXL3 may emit light of a third color. For example, the first sub-pixel SPXL1 may be a red pixel emitting red light, the second sub-pixel SPXL2 may be a green pixel emitting green light, and the third sub-pixel SPXL3 may be a blue pixel emitting blue light but are not limited thereto.

The first sub-pixel SPXL1, the second sub-pixel SPXL2, and the third sub-pixel SPXL3 may respectively use (or include) a light emitting element of a first color, a light emitting element of a second color, and a light emitting element of a third color as a light source, thereby emitting light of the first color, the second color, and the third color, respectively. In another embodiment, the first sub-pixel SPXL1, the second sub-pixel SPXL2, and the third sub-pixel SPXL3 may include light emitting elements that emit light of the same color and may include a color conversion layer and/or a color filter of different colors disposed on the light emitting element to emit light of the first color, the second color, and the third color. However, the color, type, and/or number of the sub-pixels SPXL1 to SPXL3 constituting each pixel PXL are not particularly limited. That is, the color of light emitted from each pixel PXL may be variously changed.

The sub-pixels SPXL1 to SPXL3 may be regularly arranged according to a stripe or a PenTile® (e.g., an RGBG arrangement) arrangement structure. PenTile® is a registered trademark of Samsung Display Co., Ltd. For example, the sub-pixels SPXL1 to SPXL3 may be sequentially and repeatedly disposed in the first direction DR1 and may also be repeatedly disposed in the second direction DR2. At least one sub-pixel SPXL1 to SPXL3 disposed adjacent to each other may constitute one pixel PXL configured to emit light of various colors. However, an arrangement structure of the sub-pixels SPXL1 to SPXL3 is not limited thereto, and the sub-pixels SPXL1 to SPXL3 may be arranged in the display area DA in various structures and/or methods.

Each of the sub-pixels SPXL1 to SPXL3 may be consist of an active pixel. For example, each of the sub-pixels SPXL1 to SPXL3 may include at least one light source (e.g., a light emitting element) that is driven by a control signal (e.g., a scan signal and a data signal) and/or a power supply (e.g., a first power supply and a second power supply). However, the type, structure, and/or driving method of the sub-pixels SPXL1 to SPXL3 applicable to the display device are not particularly limited.

Hereinafter, the first sub-pixel SPXL1, the second sub-pixel SPXL2, and the third sub-pixel SPXL3 are collectively referred to as sub-pixels SPXL.

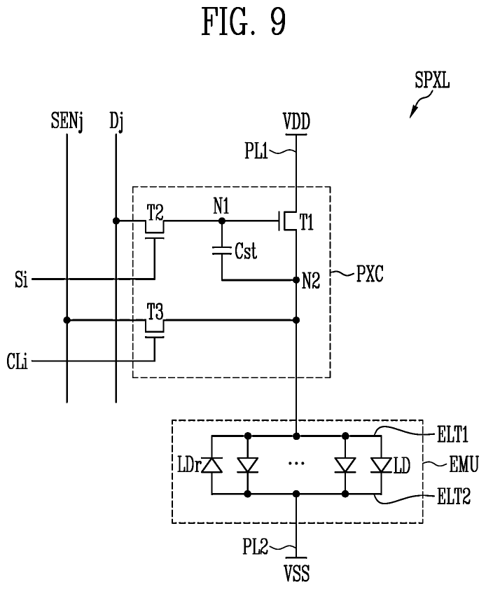

FIG. 9 is a circuit diagram of a sub-pixel included in the display device shown in FIG. 8.

Referring to FIGS. 1 to 3, 8, and 9, the sub-pixel SPXL may include a light emitting unit EMU that generates light with a luminance corresponding to a data signal and may selectively further include a pixel circuit PXC for driving the light emitting unit EMU.

The light emitting unit EMU may include a plurality of light emitting elements LD connected in parallel between a first power line PL1 connected to a first driving power supply VDD and to which a voltage of the first driving power supply VDD is applied and a second power line PL2 connected to a second driving power supply VSS and to which a voltage of the second driving power supply VSS is applied. For example, the light emitting unit EMU may include a first pixel electrode ELT1 connected to the first driving power supply VDD via the pixel circuit PXC and the first power line PL1, a second pixel electrode ELT2 connected to the second driving power supply VSS through the second power line PL2, and a plurality of light emitting elements LD connected in parallel in the same direction between the first and second pixel electrodes ELT1 and ELT2. In an embodiment, the first pixel electrode ELT1 may be an anode, and the second pixel electrode ELT2 may be a cathode.

Each of the light emitting elements LD included in the light emitting unit EMU may have one end connected to the first driving power supply VDD through the first pixel electrode ELT1 and another end connected to the second driving power supply VSS through the second pixel electrode ELT2. The first driving power supply VDD and the second driving power supply VSS may have different potentials from each other. For example, the first driving power VDD may be set as a high potential power, and the second driving power VSS may be set as a low potential power. At this time, a potential difference between the first and second driving power supplies VDD and VSS may be set to a threshold voltage or higher of the light emitting elements LD during the light emitting period of the pixel PXL.

As described above, each of the light emitting elements LD connected in parallel in the same direction (e.g., a forward direction) between the first pixel electrode ELT1 and the second pixel electrode ELT2 to which voltages of different power supplies are supplied may constitute an effective light source.

In one embodiment, the light emitting elements LD of the light emitting unit EMU may emit light with a luminance corresponding to a driving current supplied through the corresponding pixel circuit PXC. For example, during each frame period, a driving current corresponding to a grayscale value of corresponding frame data of the pixel circuit PXC may be supplied to the light emitting unit EMU. The driving current supplied to the light emitting unit EMU may be divided and may flow into each of the light emitting elements LD. Accordingly, while each light emitting element LD emits light with luminance corresponding to the current flowing therein, the light emitting unit EMU may emit light of luminance corresponding to the driving current.

In the above-described embodiment, both ends of the light emitting elements LD have been described to be connected in the same direction between the first and second driving power supplies VDD and VSS, but they are not limited thereto. According to another embodiment, the light emitting unit EMU may further include at least one non-effective light source, for example, a reverse light emitting element LDr, in addition to the light emitting elements LD, each constituting an effective light source. The reverse light emitting element LDr may be connected in parallel between the first and second pixel electrodes ELT1 and ELT2 together with the light emitting elements LD constituting the effective light sources and may be connected between the first and second pixel electrodes ELT1 and ELT2 in opposite directions to the light emitting elements LD. The reverse light emitting element LDr may maintain an inactive state even when a driving voltage (e.g., a forward driving voltage) is applied between the first and second pixel electrodes ELT1 and ELT2 so that substantially no current flows through the reverse light emitting element LDr.

The pixel circuit PXC may be connected to a scan line Si and a data line Dj of the pixel PXL. The pixel circuit PXC may also be connected to a control line CLi and a sensing line SENj of the pixel PXL. For example, when the pixel PXL is disposed in the i-th row and j-th column of the display area DA, the pixel circuit PXC of the pixel PXL may be connected to the i-th scan line Si, the j-th data line Dj, the i-th control line CLi, and the j-th sensing line SENj of the display area DA.

The pixel circuit PXC may include first to third transistors T1 to T3 and a storage capacitor Cst.

The first transistor T1 may be a driving transistor for controlling the driving current applied to the light emitting unit EMU and may be connected between the first driving power supply VDD and the light emitting unit EMU. The first terminal of the first transistor T1 may be connected (or accessed) to the first driving power supply VDD through the first power line PL1, the second terminal of the first transistor T1 may be connected to the second node N2, and the gate electrode of the first transistor T1 may be connected to the first node N1. The first transistor T1 may control an amount of the driving current applied from the first driving power supply VDD to the light emitting unit EMU through the second node N2 according to a voltage applied to the first node N1. In an embodiment, the first terminal of the first transistor T1 may be a drain electrode and the second terminal of the first transistor T1 may be a source electrode but are not limited thereto. According to other embodiments, the first terminal may be a source electrode and the second terminal may be a drain electrode.

The second transistor T2 may be a switching transistor that selects the pixel PXL in response to the scan signal and activates the pixel PXL and may be connected between the data line Dj and the first node N1. The first terminal of the second transistor T2 may be connected to the data line Dj, the second terminal of the second transistor T2 may be connected to the first node N1, and the gate electrode of the second transistor T2 may be connected to the scan line Si. The first terminal and the second terminal of the second transistor T2 may be different terminals. For example, when the first terminal is the drain electrode, the second terminal may be the source electrode.

The second transistor T2 may be turned on when a scan signal of a gate-on voltage (e.g., a high level voltage) is supplied from the scan line Si, thereby electrically connecting the data line Dj and the first node N1. The first node N1 may be a point at where the second terminal of the second transistor T2 and the gate electrode of the first transistor T1 are connected, and the second transistor T2 may transfer the data signal to the gate electrode of the first transistor T1.

The third transistor T3 may obtain a sensing signal through the sensing line SENj by connecting the first transistor T1 to the sensing line SENj and may detect characteristics of the pixel PXL including a threshold voltage of the first transistor T1 and the like by using the sensing signal. Information about the characteristics of the pixels PXL may be used to convert image data so that characteristic deviations between the pixels PXL can be compensated. The second terminal of the third transistor T3 may be connected to the second terminal of the first transistor T1, the first terminal of the third transistor T3 may be connected to the sensing line SENj, and the gate electrode of the third transistor T3 may be connected to the control line CLi. Also, the first terminal of the third transistor T3 may be connected to the initialization power supply. The third transistor T3 may be an initialization transistor configured to initialize the second node N2 and may be turned on when a sensing control signal is supplied from the control line CLi to supply a voltage of the initialization power supply to the second node N2. Accordingly, a second storage electrode of the storage capacitor Cst connected to the second node N2 may be initialized.

A first storage electrode of the storage capacitor Cst may be connected to the first node N1, and the second storage electrode of the storage capacitor Cst may be connected to the second node N2. The storage capacitor Cst may charge a data voltage corresponding to a data signal supplied to the first node N1 during one frame period. Accordingly, the storage capacitor Cst may store a voltage corresponding to a difference between the voltage of the gate electrode of the first transistor T1 and the voltage of the second node N2.

In FIG. 9, the light emitting elements LD constituting the light emitting unit EMU are all described as being connected in parallel, but embodiment are not limited thereto. According to other embodiments, the light emitting unit EMU may be configured to include at least one serial set (or stage) including a plurality of light emitting elements LD connected in parallel with each other. That is, the light emitting unit EMU may be configured as a series/parallel mixed structure.

In FIG. 9, the transistors T1 to T3 included in the pixel circuit PXC are illustrated as all n-type transistors but are not necessarily limited thereto. For example, at least one of the transistors T1 to T3 may be changed to a p-type transistor.

In addition, the structure and driving method of the sub-pixel SPXL may be variously changed. For example, the pixel circuit PXC may include pixel circuits having various structures and/or driving methods other than that of the embodiment shown in FIG. 9.

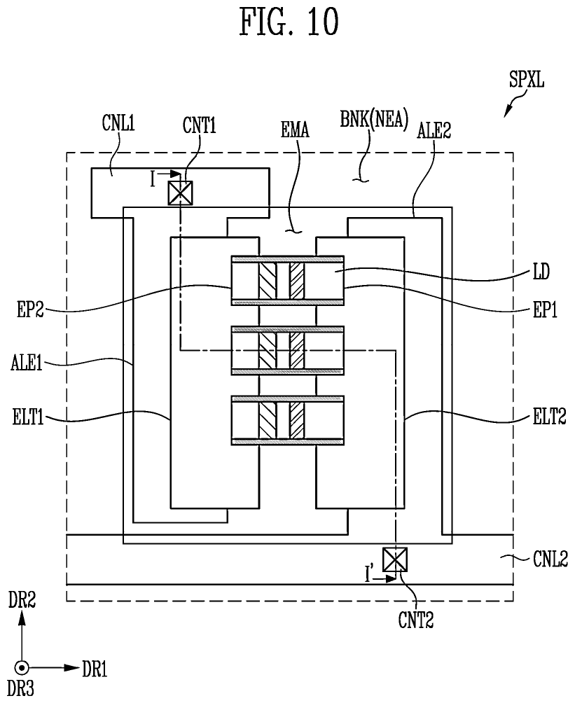

FIG. 10 is a schematic plan view of a sub-pixel included in the display device shown in FIG. 8. FIG. 10 explains some components included in the sub-pixel SPXL but may omit others not necessary for understanding the present disclosure.

Referring to FIG. 10, the sub-pixel SPXL may include a bank BNK, first and second pixel electrodes ELT1 and ELT2, first and second alignment electrodes ALE1 and ALE2, first and second connection electrodes CNL1 and CNL2, and a light emitting element LD.

The bank BNK may partition the sub-pixels SPXL, and the emission area EMA may correspond to an opening defined by the bank BNK. In one embodiment, the bank BNK may form a space in which a fluid can be accommodated. For example, during a manufacturing process, an ink including the light emitting element LD may be provided to (e.g., deposited into) a space in which the fluid can be accommodated.

The non-emission area NEA may be an area substantially corresponding to the bank BNK. When viewed in a plan view, the bank BNK may surround the emission area EMA.

The sub-pixel SPXL may include the first and second alignment electrodes ALE1 and ALE2. In one embodiment, the first and second alignment electrodes ALE1 and ALE2 may act as an electrode for aligning the light emitting element LD and an electrode for applying a voltage (e.g., a predetermined voltage or an alignment voltage).

The first and second alignment electrodes ALE1 and ALE2 may extend in the second direction DR2 and may be spaced apart from each other in the first direction DR1.

The first connection electrode CNL1 may be disposed on the same layer as the first alignment electrode ALE1 and integrally formed therewith. The second connection electrode CNL2 may be disposed on the same layer as the second alignment electrode ALE2 and integrally formed therewith.

The first and second alignment electrodes ALE1 and ALE2 may act as alignment electrodes for the light emitting element LD. For example, the light emitting elements LD may be arranged based on (or according to) electrical signals provided to the first and second alignment electrodes ALE1 and ALE2.

The light emitting elements LD may be arranged in a parallel structure in the second direction DR2. However, the arrangement structure of the light emitting element LD is not limited thereto.

The light emitting element LD may be disposed between (or on) the first and second alignment electrodes ALE1 and ALE2 when viewed in a plan view.

In one embodiment, the first pixel electrode ELT1 may be disposed on the first alignment electrode ALE1 when viewed in a plan view and electrically connected to the first alignment electrode ALE1. The second pixel electrode ELT2 may be disposed on the second alignment electrode ALE2 when viewed in a plan view and electrically connected to the second alignment electrode ALE2.

The light emitting element LD may be electrically connected to the first alignment electrode ALE1 through the first pixel electrode ELT1 and electrically connected to the second alignment electrode ALE2 through the second pixel electrode ELT2.

The second end EP2 of the light emitting element LD may be electrically connected to the first pixel electrode ELT1. The first end EP1 of the light emitting element LD may be electrically connected to the second pixel electrode ELT2.

The first semiconductor layer (e.g., the first semiconductor layer SEC1 shown in FIG. 1) of the light emitting element LD may be electrically connected to the second pixel electrode ELT2. The second semiconductor layer (e.g., the second semiconductor layer SEC2 shown in FIG. 1) of the light emitting element LD may be electrically connected to the first pixel electrode ELT1.

The first and second alignment electrodes ALE1 and ALE2 may be electrically connected to the pixel circuit PXC and/or the power line. For example, the first alignment electrode ALE1 may be electrically connected to the pixel circuit PXC and/or the first power line PL1 through a first contact hole (e.g., a first contact opening) CNT1 formed in the first connection electrode CNL1, and the second alignment electrode ALE2 may be electrically connected to the pixel circuit PXC and/or the second power line PL2 through a second contact hole (e.g., a second contact opening) CNT2 formed in the second connection electrode CNL2.

In FIG. 10, the first pixel electrode ELT1 may be connected to the first power line PL1 through the first alignment electrode ALE1, and the second pixel electrode ELT2 may be connected to the second power line PL2 through the second alignment electrode ALE2, but the present disclosure is not limited thereto. For example, the first pixel electrode ELT1 may be directly connected to the first power line PL1 through a separate contact portion without passing through the first alignment electrode ALE1. The second pixel electrode ELT2 may also be directly connected to the second power line PL2 through a separate contact portion without passing through the second alignment electrode ALE2.

When the light emitting element LD is provided in the sub-pixel SPXL, the light emitting element LD may be arranged between the first and second alignment electrodes ALE1 and ALE2 in a forward direction or may be arranged between the first and second alignment electrodes ALE1 and ALE2 in a reverse direction. When arranged in the forward direction, the light emitting elements LD may constitute an effective light source, and when arranged in the reverse direction, the light emitting elements LD may constitute an ineffective light source.

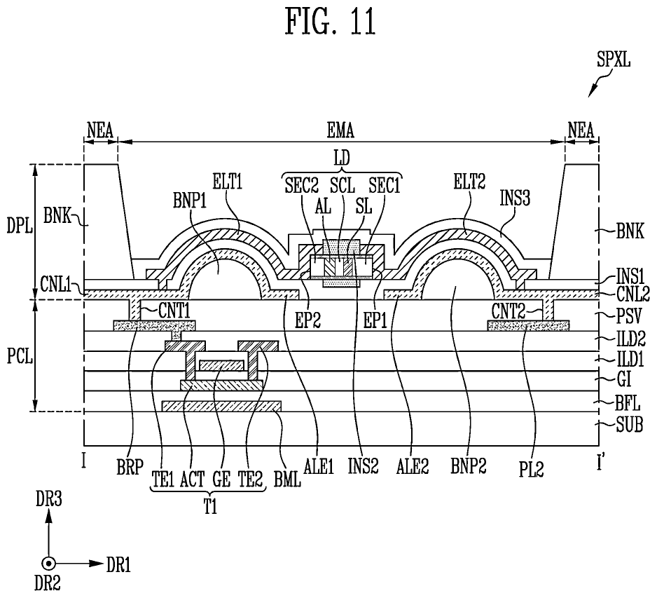

FIG. 11 is a schematic cross-sectional view taken along the line I-I′ of FIG. 10.

Referring to FIGS. 9 to 11, the sub-pixel SPXL may include the substrate SUB, a pixel circuit layer PCL, and a display element layer DPL. Hereinafter, for convenience of description, the first transistor T1 from among the first to third transistors T1 to T3 described above will be described as a reference.

The substrate SUB may constitute a base member of the display device DD. The substrate SUB may be a rigid or flexible substrate or film but is not limited to a specific example. According to an embodiment, the substrate SUB may include polyimide. The substrate SUB may be provided as a base surface, and the pixel circuit layer PCL and the display element layer DPL may be disposed on the substrate SUB.

The pixel circuit layer PCL may be disposed on the substrate SUB. The pixel circuit layer PCL may include a lower electrode layer BML, a buffer layer BFL, a first transistor T1, a gate insulating layer GI, a first interlayer insulating layer ILD1, a second interlayer insulating layer ILD2, a bridge pattern BRP, a second power line PL2, a passivation layer PSV, a first contact portion CNT1, and a second contact portion CNT2.

The lower electrode layer BML may be disposed on the substrate SUB and may be covered by the buffer layer BFL. A portion of the lower electrode layer BML may overlap the first transistor T1 when viewed in a plan view.

The lower electrode layer BML may include a conductive material and may act as a path through which electrical signals provided to the pixel circuit layer PCL and the display element layer DPL move. For example, the lower electrode layer BML may include any one of aluminum (Al), copper (Cu), titanium (Ti), and molybdenum (Mo).

The buffer layer BFL may be disposed on the substrate SUB. The buffer layer BFL may prevent impurities from being diffused from the outside. The buffer layer BFL may include at least one of a metal oxide, such as silicon nitride (SiNₓ), silicon oxide (SiOₓ), silicon oxynitride (SiOₓN_{y}), aluminum oxide (AlOₓ), and the like.

The first transistor T1 may be electrically connected to the light emitting element LD. The first transistor T1 may be electrically connected to the bridge pattern BRP. However, the first transistor T1 is not limited to the above-described examples. In other embodiments, the first transistor T1 may be directly electrically connected to the first connection electrode CNL1 without passing through the bridge pattern BRP.

The first transistor T1 may include an active layer ACT, a first transistor electrode TE1, a second transistor electrode TE2, and a gate electrode GE.

The active layer ACT may refer to a semiconductor layer. The active layer ACT may be disposed on the buffer layer BFL. For example, the active layer ACT may include any one of polysilicon, low temperature polycrystalline silicon (LTPS), amorphous silicon, and an oxide semiconductor.

The active layer ACT may have a first contact region in contact with the first transistor electrode TE1 and a second contact region in contact with the second transistor electrode TE2. The first contact region and the second contact region may be a semiconductor pattern doped with impurities. A region between the first contact region and the second contact region may be a channel region. The channel region may be an intrinsic semiconductor pattern that is not doped with impurities.

The gate electrode GE may be disposed on the gate insulating layer GI. A position of the gate electrode GE may correspond to a position of the channel region of the active layer ACT. For example, the gate electrode GE may be disposed on (e.g., over) the channel region of the active layer ACT with the gate insulating layer GI interposed therebetween. According to an embodiment, the gate electrode GE may include any one of aluminum (Al), copper (Cu), titanium (Ti), and molybdenum (Mo).

The gate insulating layer GI may be disposed on the active layer ACT. The gate insulating layer GI may include an inorganic material. According to an embodiment, the gate insulating layer GI may include at least one of silicon nitride (SiNₓ), silicon oxide (SiOₓ), silicon oxynitride (SiOₓN_{y}), and aluminum oxide (AlOₓ).

The first interlayer insulating layer ILD1 may be disposed on the gate electrode GE. Similar to the gate insulating layer GI, the first interlayer insulating layer ILD1 may include at least one of silicon nitride (SiNₓ), silicon oxide (SiOₓ), silicon oxynitride (SiOₓN_{y}), and aluminum oxide (AlOₓ).

The first transistor electrode TE1 and the second transistor electrode TE2 may be disposed on the first interlayer insulating layer ILD1. The first transistor electrode TE1 may penetrate (e.g., may extend through) the gate insulating layer GI and the first interlayer insulating layer ILD1 to contact the first contact region of the active layer ACT, and the second transistor electrode TE2 may penetrate the gate insulating layer GI and the first interlayer insulating layer ILD1 to contact the second contact region of the active layer ACT. According to an embodiment, the first transistor electrode TE1 may be a drain electrode, and the second transistor electrode TE2 may be a source electrode but are not limited thereto.

The second interlayer insulating layer ILD2 may be disposed on the first transistor electrode TE1 and the second transistor electrode TE2. Similar to the first interlayer insulating layer ILD1 and the gate insulating layer GI, the second interlayer insulating layer ILD2 may include an inorganic material. The inorganic material may include materials exemplified as constituent materials of the first interlayer insulating layer ILD1 and the gate insulating layer GI, for example, at least one of silicon nitride (SiNₓ), silicon oxide (SiOₓ), silicon oxynitride (SiOₓN_{y}), and aluminum oxide (AlOₓ).

The bridge pattern BRP may be disposed on the second interlayer insulating layer ILD2. The bridge pattern BRP may be connected to the first transistor electrode TE1 through a contact hole (e.g., a contact opening) passing through the second interlayer insulating layer ILD2. The bridge pattern BRP may be electrically connected to the first connection electrode CNL1 through the first contact portion CNT1 formed in (e.g., passing through) the passivation layer PSV.

The second power line PL2 may be disposed on the second interlayer insulating layer ILD2. The second power line PL2 may be electrically connected to the second connection electrode CNL2 through the second contact portion CNT2 formed in (e.g., passing through) the passivation layer PSV. The second power line PL2 may provide the second driving power supply (or a cathode signal) to the light emitting element LD through the second pixel electrode ELT2.

The passivation layer PSV may be disposed on the second interlayer insulating layer ILD2. The passivation layer PSV may cover the bridge pattern BRP and the second power line PL2. The passivation layer PSV may be a via layer. The passivation layer PSV may be provided in a form including an organic insulating layer, an inorganic insulating layer, or the organic insulating layer disposed on the inorganic insulating layer but is not limited thereto.

The first contact portion CNT1 connected to one area of the bridge pattern BRP and the second contact portion CNT2 connected to one area of the second power line PL2 may be formed in the passivation layer PSV.

The display element layer DPL may be disposed on the pixel circuit layer PCL. The display element layer DPL may include first and second bank patterns BNP1 and BNP2, the bank BNK, the first and second connection electrodes CNL1 and CNL2, the first and second alignment electrodes ALE1 and ALE2, the first and second pixel electrodes ELT1 and ELT2, the light emitting element LD, and first, second, and third insulating layers INS1, INS2, and INS3.

The first and second bank patterns BNP1 and BNP2 may be disposed on the passivation layer PSV. The first and second bank patterns BNP1 and BNP2 may protrude in a display direction (e.g., the third direction DR3). In one embodiment, the first and second bank patterns BNP1 and BNP2 may include an organic material or an inorganic material but are not limited thereto.

The first and second connection electrodes CNL1 and CNL2 may be disposed on the passivation layer PSV. The first connection electrode CNL1 may be connected to the first alignment electrode ALE1. The first connection electrode CNL1 may be electrically connected to the bridge pattern BRP through the first contact portion CNT1. The first connection electrode CNL1 may electrically connect the bridge pattern BRP and the first alignment electrode ALE1. The second connection electrode CNL2 may be connected to the second alignment electrode ALE2. The second connection electrode CNL2 may be electrically connected to the second power line PL2 through the second contact portion CNT2. The second connection electrode CNL2 may electrically connect the second power line PL2 and the second alignment electrode ALE2.

The first and second alignment electrodes ALE1 and ALE2 may be disposed on the passivation layer PSV (or a base layer). At least a portion of the first alignment electrode ALE1 may be arranged on the first bank pattern BNP1, at least a portion of the second alignment electrode ALE2 may be arranged on the second bank pattern BNP2, and each thereof may act as a reflective partition wall.

The first alignment electrode ALE1 may be electrically connected to the first pixel electrode ELT1 through a contact hole (e.g., a contact opening) formed in the first insulating layer INS1. The first pixel electrode ELT1 may receive an anode signal of the light emitting element LD through the first alignment electrode ALE1.

The second alignment electrode ALE2 may be electrically connected to the second pixel electrode ELT2 through a contact hole (e.g., a contact opening) formed in the first insulating layer INS1. The second pixel electrode ELT2 may receive a cathode signal (e.g., a ground signal) of the light emitting element LD through the second alignment electrode ALE2.

The first and second alignment electrodes ALE1 and ALE2 may include a conductive material. For example, the first and second alignment electrodes ALE1 and ALE2 may include a metal, such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and alloys thereof. However, the first and second alignment electrodes ALE1 and ALE2 are not limited to the above-described examples.

The first insulating layer INS1 may be disposed on the passivation layer PSV. The first insulating layer INS1 may cover the first and second alignment electrodes ALE1 and ALE2. The first insulating layer INS1 may include at least one of silicon nitride (SiNₓ), silicon oxide (SiOₓ), silicon oxynitride (SiOₓN_{y}), and aluminum oxide (AlOₓ).

The bank BNK may be disposed on the first insulating layer INS1. The bank BNK may have a thickness in the display direction (e.g., the third direction DR3) and may have an opening corresponding to the emission area EMA. The bank BNK may include an organic material or an inorganic material but is not limited thereto.

The light emitting element LD may be disposed on the first insulating layer INS1 and may emit light based on electrical signals provided from the first and second pixel electrodes ELT1 and ELT2.

The second insulating layer INS2 (or an insulating pattern) may be disposed on the light emitting element LD. The second insulating layer INS2 may cover a portion of the light emitting element LD. The second insulating layer INS2 may include an organic material. However, the second insulating layer INS2 is not limited thereto, and the second insulating layer INS2 may include an inorganic material. At least a portion of the second insulating layer INS2 may fill a gap (or a cavity) under the light emitting element LD.

The first and second pixel electrodes ELT1 and ELT2 may be disposed on the first insulating layer INS1 and the second insulating layer INS2. The first pixel electrode ELT1 may electrically connect the first alignment electrode ALE1 and the light emitting element LD, and the second pixel electrode ELT2 may electrically connect the second alignment electrode ALE2 and the light emitting element LD.

The first pixel electrode ELT1 may provide an anode signal to the light emitting element LD, and the second pixel electrode ELT2 may provide a cathode signal to the light emitting element LD.

The first and second pixel electrodes ELT1 and ELT2 may include a conductive material. In one embodiment, the first and second pixel electrodes ELT1 and ELT2 may be formed in the same process and may include the same material. For example, the first and second pixel electrodes ELT1 and ELT2 may include a transparent conductive material including indium tin oxide (ITO), indium zinc oxide (IZO), and indium tin zinc oxide (ITZO), but is not limited thereto.

The third insulating layer INS3 may be disposed on the first and second pixel electrodes ELT1 and ELT2 and the second insulating layer INS2 to protect components of the display element layer DPL from external influences (e.g., moisture, etc.). For example, the third insulating layer INS3 may include at least one of silicon nitride (SiNₓ), silicon oxide (SiOₓ), silicon oxynitride (SiOₓN_{y}), and aluminum oxide (AlOₓ).

The structure of the sub-pixel SPXL is not limited to the example described above with reference to FIG. 11, and various embodiments may be implemented.

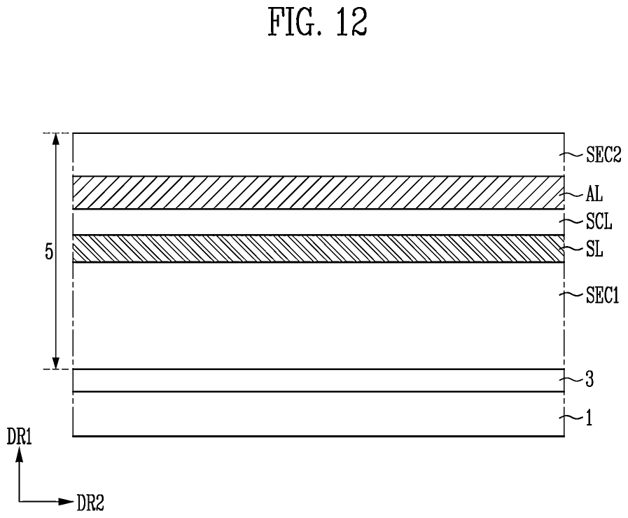

FIGS. 12 to 15 are schematic plan views showing steps of a manufacturing method of a light emitting element according to an embodiment of the present disclosure.

Referring to FIG. 12, a stacked substrate 1 may be prepared, and an undoped semiconductor layer 3 may be formed on the stacked substrate 1. Then, the first semiconductor layer SEC1, the first auxiliary layer SL, the second auxiliary layer SCL, the active layer AL, and the second semiconductor layer SEC2 may be sequentially formed on the undoped semiconductor layer 3 in the first direction DR1.

The stacked substrate 1 may be a wafer for epitaxial growth of a material (e.g., a predetermined material). According to an embodiment, the stacked substrate may be any one of a sapphire substrate, a GaAs substrate, a Ga substrate, and an InP substrate but is not limited thereto.

For example, when a specific material satisfies the selectivity for manufacturing the light emitting element LD and epitaxial growth of a specific material can smoothly occur, the specific material can be selected as a material of the stacked substrate 1. A surface of the stacked substrate 1 may be smooth. A shape of the stacked substrate 1 may be a polygonal shape including a rectangle or a circular shape but is not limited thereto.

According to an embodiment, the undoped semiconductor layer 3 may be a highly doped semiconductor layer of the first semiconductor layer SEC1 and may be a semiconductor layer to which dopants are not provided to suppress defects in the first semiconductor layer SEC1. According to an embodiment, the undoped semiconductor layer 3 may include any one of semiconductor materials of InAlGaN, GaN, AlGaN, InGaN, AlN, and InN, but a separate dopant may not be provided in the undoped semiconductor layer 3. An etching rate of the undoped semiconductor layer 3 to which no dopant is provided may be different from an etching rate of the first semiconductor layer SEC1. The undoped semiconductor layer 3 may be formed by any one method of metal organic chemical vapor-phase deposition (MOCVD), molecular beam epitaxy (MBE), vapor phase epitaxy (VPE), and liquid phase epitaxy (LPE).

The first semiconductor layer SEC1, the first auxiliary layer SL, the second auxiliary layer SCL, and the active layer AL may be provided by epitaxial growth. A formation method for the undoped semiconductor layer 3 may be provided by any one of the methods listed as examples.

To form the first auxiliary layer SL, first and second thin film layers (e.g., the first and second thin film layers SLa and SLb shown in FIG. 3) may be alternately formed on the first semiconductor layer SEC1. To form the second auxiliary layer SCL, third and fourth thin film layers (e.g., the third and fourth thin film layers SCLa and SCLb shown in FIG. 3) may be alternately formed on the first auxiliary layer SL. In one embodiment, the first thin film layer SLa and the third thin film layer SCLa may be GaN, and the second thin film layer SLb and the fourth thin film layer SCLb may be InGaN. In a step of forming the first thin film layer SLa of the first auxiliary layer SL, an implantation concentration of gallium Ga is a first gallium concentration, and in a step of forming the third thin film layer SCLa of the second auxiliary layer SCL, an implantation concentration of gallium may be a second gallium concentration that is higher than the first gallium concentration. In one embodiment, in a step of forming the second thin film layer SLb of the first auxiliary layer SL, an injection concentration of indium (In) is a first injection concentration, and in a step of forming the fourth thin film layer SCLb of the second auxiliary layer SCL, an injection concentration of indium may be a second indium concentration equal to or greater than the first indium concentration.

To form the active layer AL, a barrier layer (e.g., the barrier layer ALa shown in FIG. 3) and a well layer (e.g., the well layer ALb shown in FIG. 3) may be alternately formed. The barrier layer ALa may include at least one of GaN, InGaN, AlGaP, and AlGaAs. The well layer ALb may include at least one of GaInP, AlGaInP, InGaN, and InGaAsP. In a step of forming the barrier layer ALa, the implantation concentration of gallium may be higher than that of each of the first thin film layer SLa and the third thin film layer SCLa. In a step of forming the well layer ALb, the implantation concentration of indium may be higher than that of each of the second thin film layer SLb and the fourth thin film layer SCLb. In one embodiment, when the second thin film layer SLb, the fourth thin film layer SCLb, and the well layer ALb are InₓGa₁₋ₓN (where 0<x<1), the indium composition ratio included in the second thin film layer SLb may be about 4%, the indium composition ratio included in the fourth thin film layer SCLb may be about 4% to about 13%, and the indium composition ratio included in the well layer ALb may be about 15% to about 17%.

The second semiconductor layer SEC2 may be formed on the active layer AL. The second semiconductor layer SEC2 may be provided by epitaxial growth.

According to an embodiment, the first semiconductor layer SEC1, the first auxiliary layer SL, the second auxiliary layer SCL, and the active layer AL, and the second semiconductor layer SEC2, which are sequentially stacked on the stacked substrate 1 and the undoped semiconductor layer 3, may be provided (or formed) as a light emitting stacked structure 5.

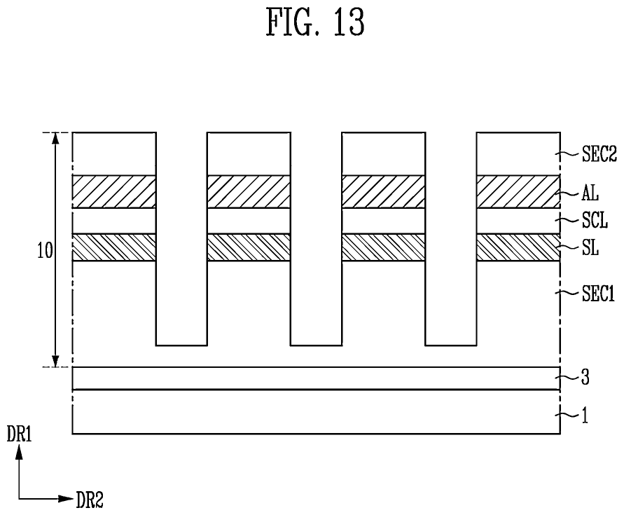

Referring to FIG. 13, the light emitting stacked structure 5 may be etched in a stacked direction to form the light emitting stacked pattern 10. The light emitting stacked pattern 10 may correspond to the etched and removed area in the stacked direction and may refer to a structure including the first semiconductor layer SEC1, the first auxiliary layer SL, the second auxiliary layer SCL, the active layer AL, and the second semiconductor layer SEC2 are sequentially arranged. The stacked direction may refer to a direction perpendicular to (or normal to) a main surface of the stacked substrate 1 (e.g., the first direction DR1).

According to an embodiment, to form the light emitting stacked pattern 10, a mask may be disposed on (or over) an entire surface of the light emitting stacked structure 5, and an etching process is performed to pattern at a nano-scale to a micro-scale. According to an embodiment, an etching process for forming the light emitting stacked pattern 10 may be a dry etching method. The dry etching method may be any one of reactive ion etching (RIE), reactive ion beam etching (RIBE), and inductively coupled plasma reactive ion etching (ICP-RIE).

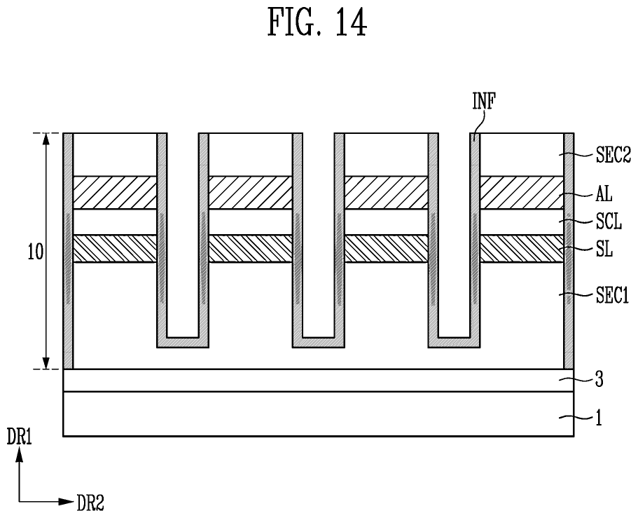

Referring to FIG. 14, an insulating film INF may be formed on the first semiconductor layer SEC1, the first auxiliary layer SL, the second auxiliary layer SCL, the active layer AL, and the second semiconductor layer SEC2.

The insulating film INF may cover the first semiconductor layer SEC1, the first auxiliary layer SL, the second auxiliary layer SCL, the active layer AL, and the second semiconductor layer SEC2.

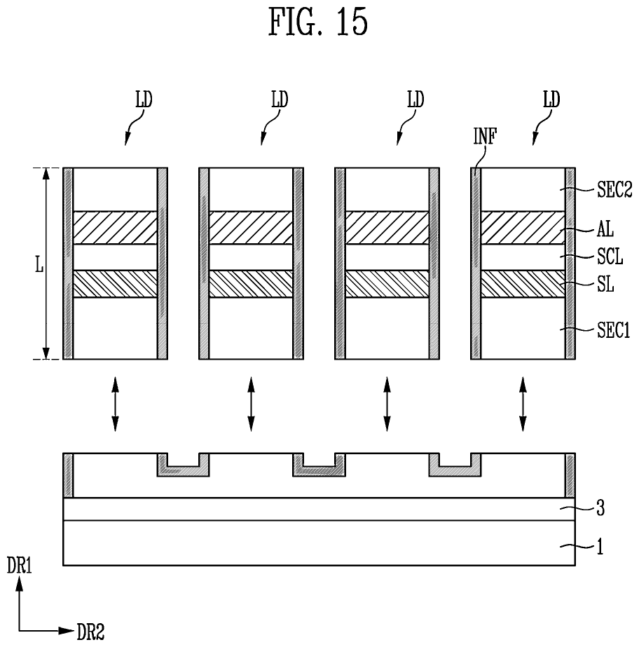

Referring to FIG. 15, the light emitting stacked pattern 10 may be separated from the stacked substrate 1 and the undoped semiconductor layer 3. According to an embodiment, the light emitting stacked pattern 10 may be separated by a laser lift-off (LLO) or chemical lift-off (CLO) method. According to an embodiment, the light emitting stacked pattern 10 may be separated by sonication.

A light emitting element and a manufacturing method thereof, according to embodiments of the present disclosure, can minimize or improve a decrease in a quantum efficiency and a wavelength change by including an auxiliary layer having an indium composition ratio between that of the active layer and that of a superlattice layer of the light emitting element between the active layer and the superlattice layer of the light emitting element. In addition, the light emitting element and the manufacturing method thereof, according to embodiments of the present disclosure, can block defective elements from flowing into the active layer through a stress control layer, thereby improving reliability.

Although the present disclosure has been described with reference to embodiments thereof, those skilled in the art will understand that various modifications and changes can be made to the embodiments described herein without departing from the spirit and scope of the present disclosure as set forth in the claims and their equivalents.

What is claimed is:

1. A light emitting element comprising:
a first semiconductor layer of a first type;
a first auxiliary layer on the first semiconductor layer and having a first indium composition ratio;
a second auxiliary layer on the first auxiliary layer and having a second indium composition ratio;
an active layer comprising barrier layers and well layers that are alternately arranged on the second auxiliary layer and having a third indium composition ratio; and
a second semiconductor layer on the active layer and of a second type different from the first type,
wherein the second indium composition ratio is greater than the first indium composition ratio and is less than the third indium composition ratio.

2. The light emitting element of claim 1, wherein a thickness of the first auxiliary layer is thicker than a thickness of the second auxiliary layer and is thinner than a thickness of the active layer.

3. The light emitting element of claim 2, wherein the first auxiliary layer has a first gallium composition ratio,
wherein the second auxiliary layer has a second gallium composition ratio,
wherein the active layer has a third gallium composition ratio, and
wherein the second gallium composition ratio is greater than the first gallium composition ratio and is less than the third gallium composition ratio.

4. The light emitting element of claim 3, wherein the active layer comprises a plurality of pairs of the barrier layer and the well layer.

5. The light emitting element of claim 4, wherein each of the first auxiliary layer and the second auxiliary layer comprises a pair of a first thin film layer and a second thin film layer, and
wherein a thickness of the well layer of the active layer is thicker than a thickness of the second thin film layer of the first auxiliary layer and the second auxiliary layer.

6. The light emitting element of claim 5, wherein the first thin film layer comprise sGaN, and
wherein the second thin film layer comprises InGaN.

7. The light emitting element of claim 5, wherein a thickness of the barrier layer is thicker than a thickness of the first thin film layer of the second auxiliary layer and is thinner than the thickness of the first thin film layer of the first auxiliary layer.

8. The light emitting element of claim 7, wherein the first thin film layer of the second auxiliary layer adjacent to the active layer directly contacts the barrier layer of the active layer.

9. The light emitting element of claim 7, wherein a number of the barrier layer and the well layer of the active layer is greater than a number of the first thin film layer and the second thin film layer of the first auxiliary layer.

10. The light emitting element of claim 9, wherein the thickness of the second thin film layer of the second auxiliary layer is equal to or thicker than the thickness of the second thin film layer of the first auxiliary layer.

11. The light emitting element of claim 10, wherein the thickness of the first thin film layer of the first auxiliary layer is thicker than the thickness of the first thin film layer of the second auxiliary layer.

12. The light emitting element of claim 11, wherein a number of the first thin film layer and the second thin film layer of the second auxiliary layer is greater than a number of the first thin film layer and the second thin film layer of the first auxiliary layer.

13. The light emitting element of claim 5, wherein the first auxiliary layer comprises five pairs of the first thin film layer and the second thin film layer,
wherein the second auxiliary layer comprises eight pairs of the first thin film layer and the second thin film layer, and
wherein the active layer comprises eight pairs of the well layer and the barrier layer.

14. The light emitting element of claim 13, wherein the first indium composition ratio is 4% or less,
wherein the second indium composition ratio is between 4% and 13%, and
wherein the third indium composition ratio is between 15% and 17%.

15. The light emitting element of claim 1, wherein the first semiconductor layer is a semiconductor layer doped with an n-type dopant, and
wherein the second semiconductor layer is a semiconductor layer doped with a p-type dopant.

16. A manufacturing method of a light emitting element, the method comprising:
sequentially forming a first semiconductor layer, a first auxiliary layer, a second auxiliary layer, an active layer, and a second semiconductor layer in a first direction on a stacked substrate; and
etching the first semiconductor layer, the first auxiliary layer, the second auxiliary layer, the active layer, and the second semiconductor layer in a thickness direction of the stacked substrate to form a light emitting element,
wherein the forming of the first auxiliary layer on the first semiconductor layer comprises alternately disposing one more pairs of a first thin film layer having a first indium composition ratio and a second thin film layer having a first gallium composition ratio,
wherein the forming of the second auxiliary layer on the first auxiliary layer comprises alternately disposing one more pairs of a third thin film layer having a second indium composition ratio and a fourth thin film layer having a second gallium composition ratio,
wherein the forming of the active layer on the second auxiliary layer comprises alternately disposing two or more pairs of well layers having a third indium composition ratio and barrier layers having a third gallium composition ratio, and
wherein the second indium composition ratio has a value between the first indium composition ratio and the third indium composition ratio.

17. The manufacturing method of claim 16, wherein the second gallium composition ratio has a value between the first gallium composition ratio and the third gallium composition ratio.

18. The manufacturing method of claim 16, wherein a thickness of the second auxiliary layer in the first direction is thicker than a thickness of the first auxiliary layer and is thinner than a thickness of the active layer.

19. The manufacturing method of claim 16, wherein a thickness of the first thin film layer of the first auxiliary layer is thicker than a thickness of the third thin film layer of the second auxiliary layer.

20. A display device comprising:
a substrate;
a light emitting element on the substrate and having a first end and a second end facing the first end, the light emitting element comprises a second semiconductor layer, an active layer, a second auxiliary layer, a first auxiliary layer, and a first semiconductor layer sequentially arranged in a first direction, a second indium composition ratio of the second auxiliary layer being greater than a first indium composition ratio of the first auxiliary layer and being less than a third indium composition ratio of the active layer;
a first pixel electrode electrically connected to the second end of the light emitting element; and
a second pixel electrode electrically connected to the first end of the light emitting element.
